(19) United States
(12) Patent Application Publication
(10) Pub. No.: US 2025/0270693 A1
(43) Pub. Date: Aug. 28, 2025

(54) ENABLING THICK MOSI GROWTH

(71) Applicant: Applied Materials, Inc., Santa Clara, CA (US)

(72) Inventors: Muthukumar KALIAPPAN, Santa Clara, CA (US); Yang HU, Santa Clara, CA (US); Michael HAVERTY, Santa Clara, CA (US); Avgerinos V. GELATOS, Scotts Valley, CA (US)

(21) Appl. No.: 18/589,629

(22) Filed: Feb. 28, 2024

(51) Int. Cl. C23C 16/455; C23C 16/56

(52) U.S. Cl. CPC C23C 16/45527; C23C 16/45553; C23C 16/56

(57) ABSTRACT

A method includes depositing a contact capping layer over a surface of a contact structure, the contact capping layer deposition process comprising flowing hydrogen (H2) and a silicon containing gas into a processing chamber, and delivering a molybdenum (Mo) precursor for a first period of time and halting delivering of the Mo precursor for a second period of time while flowing the hydrogen (H2) and the silicon containing gas, and repeating delivering the Mo precursor and halting delivering the Mo precursor one or more times while flowing the hydrogen (H2) and the silicon containing gas.

### BACKGROUND

### Field

Embodiments of the present invention generally relate to a depositing a capping layer during contact formation.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a molybdenum silicide layer, is required to form a reliable contact at the formed source and drain regions.

In a traditional middle-end-of-the-line (MEOL) contact junction formation process, a feature also referred to a cavity, a via, or a trench, is fabricated in the semiconductor substrate. MEOL contact junctions allow connections between frontend-of-the-line (FEOL) semiconductor structures and back-end-of-the-line (BEOL) interconnects. Contacts with a low resistivity are desirable in semiconductor devices.

However, when MEOL contacts have high resistance, the contacts produce poor connections between the FEOL structures and the BEOL packaging interconnects, reducing the performance of the packaged semiconductor structures.

In traditional MEOL contact formation, a conformal contact capping layer, such as a molybdenum silicide (MoSi) layer, is formed on a silicon or silicon germanium connection as a contact capping layer. The contact capping layer is formed over the field, sidewalls and contact regions formed on the substrate. The inventors have observed, however that total device resistance is increasingly dominated by contact resistance (Rc). To achieve a better Rc, a continuous thick MoSi layer with low impurity is required. However, current MoSi layer deposition techniques do not have control over the thickness and impurities in MoSi layers.

There is a need for improved methods to reduce (improve) contact resistance by controlling the thickness and quality of the capping layer.

### SUMMARY

According to embodiments, a method includes depositing a contact capping layer over a surface of a contact structure, the contact capping layer deposition process comprising flowing hydrogen (H₂) and a silicon containing gas into a processing chamber for a first period of time, and delivering a molybdenum (Mo) precursor for a second period of time and halting delivering of the Mo precursor for a third period of time, wherein the second period of time and the third period of time overlap with the first period of time, and repeating delivering the Mo precursor and halting delivering the Mo precursor one or more times.

According to embodiments, a method includes forming a contact capping layer over a surface of a contact structure, the forming of the contact comprising (a) delivering a molybdenum (Mo) precursor for a first period of time and halting the first delivery of the Mo precursor for a second period of time; (b) delivering the molybdenum (Mo) precursor for a third period of time and halting the second delivery of the Mo precursor for a fourth period of time; (c) delivering a silicon containing gas for a fifth period of time and halting delivery of the silicon containing gas for a sixth period of time; and repeating (a), (b) and (c) one or more times while flowing hydrogen (H2).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates an integrated tool (e.g., cluster tool) in accordance to one or more embodiments.

FIG. 2 illustrates a method for depositing a contact capping layer on a substrate according to one or more embodiments.

FIGS. 3A-3B illustrate a cross-sectional view of a semiconductor structure during deposition of a contact capping layer according to one or more embodiments.

FIGS. 4A-4B illustrate timing diagrams illustrating a process for depositing a contact capping layer on a substrate according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein relate to a method for improving contact resistance of a semiconductor device by controlling the thickness and quality of a contact capping layer deposited during contact formation. Particular embodiments herein describe a method for depositing a contact capping layer having a continuous thickness with a low impurity to achieve an improved contact resistance (Rc) of the contact capping layer to adjacent metal interconnects using a soaking process.

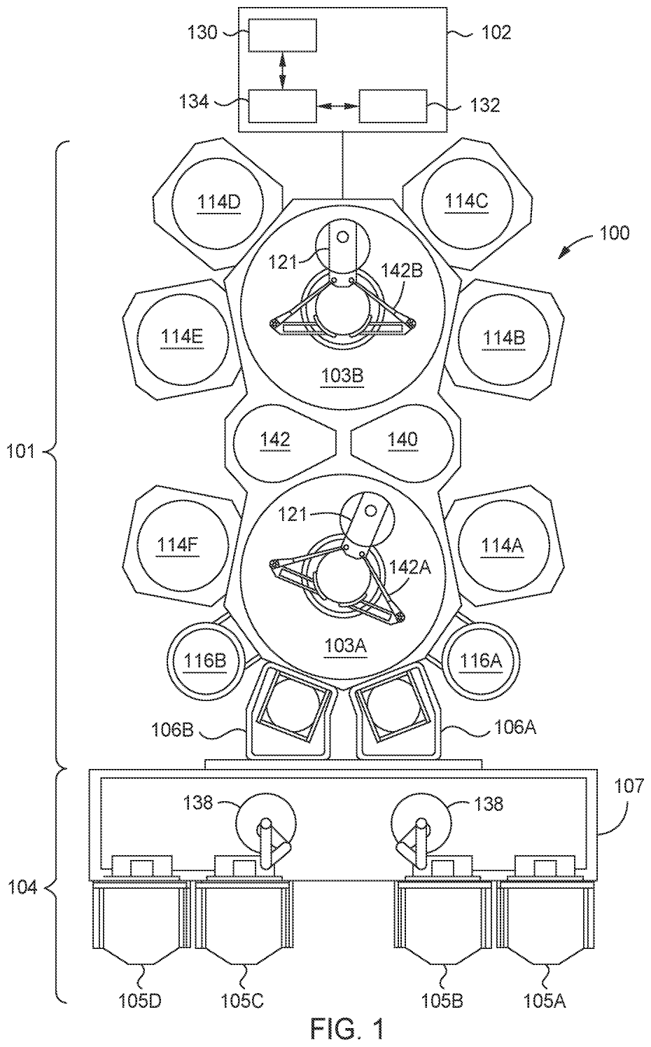

FIG. 1 illustrates an integrated tool 100 (e.g., cluster tool) in accordance to one or more embodiments. The advantage of using an integrated tool 100 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 100 includes a vacuum-tight processing platform 101, a factory interface 104, and a system controller 102. The processing platform 101 comprises multiple processing chambers, such as 114A, 114B, 114C, 114D, 114E, and 114F operatively coupled to a vacuum substrate transfer chamber (transfer chambers 103A, 103B). The factory interface 104 is operatively coupled to the transfer chamber 103A by one or more load lock chambers (two load lock chambers, such as 106A and 106B shown in FIG. 1).

In some embodiments, the factory interface 104 comprises at least one docking station 107, at least one factory interface robot 138 to facilitate the transfer of the semiconductor substrates. The docking station 107 is configured to accept one or more front opening unified pod (FOUP). Four FOUPS, such as 105A, 105B, 105C, and 105D are shown in the embodiment of FIG. 1. The factory interface robot 138 is configured to transfer the substrates from the factory interface 104 to the processing platform 101 through the load lock chambers, such as 106A and 106B. Each of the load lock chambers 106A and 106B have a first port coupled to the factory interface 104 and a second port coupled to the transfer chamber 103A. The load lock chamber 106A and 106B are coupled to a pressure control system (not shown) which pumps down and vents the load lock chambers 106A and 106B to facilitate passing the substrates between the vacuum environment of the transfer chamber 103A and the substantially ambient (e.g., atmospheric) environment of the factory interface 104. The transfer chambers 103A, 103B have vacuum robots 142A, 142B disposed in the respective transfer chambers 103A, 103B. The vacuum robot 142A is capable of transferring substrates 121 between the load lock chamber 106A, 106B, the processing chambers 114A and 114F and a cooldown station 140 or a pre-clean station 142. The vacuum robot 142B is capable of transferring substrates 121 between the cooldown station 140 or pre-clean station 142 and the processing chambers 114B, 114C, 114D, and 114E.

In some embodiments, the processing chambers 114A, 114B, 114C, 114D, 114E, and 114F are coupled to the transfer chambers 103A, 103B. The processing chambers 114A, 114B, 114C, 114D, 114E, and 114F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 116A and 116B) may be coupled to the transfer chamber 103A. The service chambers 116A and 116B may be configured to perform other substrate processes, such as degassing, orientation, substrate metrology, cool down, and the like.

The processing chambers 114A, 114B, 114C, 114D, 114E, and 114F may be any appropriate chamber for processing a substrate. In some examples, a processing chamber may be capable of performing an etch process, a cleaning process, an annealing process, a CVD deposition process, or an ALD deposition processes. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 102 controls the operation of the tool 100 using a direct control of the process chambers 114A, 114B, 114C, 114D, 114E, and 114F or alternatively, by controlling the computers (or controllers) associated with the process chambers 114A, 114B, 114C, 114D, 114E, and 114F and the tool 100. In operation, the system controller 102 enables data collection and feedback from the respective chambers and systems to optimize performance of the tool 100. The system controller 102 generally includes a Central Processing Unit (CPU) 130, a memory 134, and a support circuit 132. The CPU 130 may be any form of a general-purpose computer processor that can be used in an industrial setting. The support circuit 132 is conventionally coupled to the CPU 130 and may comprise a cache, clock circuits, input/output subsystems, power supplies, and the like. Software routines, such as a method as described above may be stored in the memory 134 and, when executed by the CPU 130, transform the CPU 130 into a specific purpose computer (system controller) 102. The software routines may also be stored and/or executed by a second controller (not shown) that is located remotely from the tool 100.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on or more computing platforms). For example, a computer readable medium may include any suitable form of volatile or non-volatile memory. In some embodiments, the computer readable media may include a non-transitory computer readable medium.

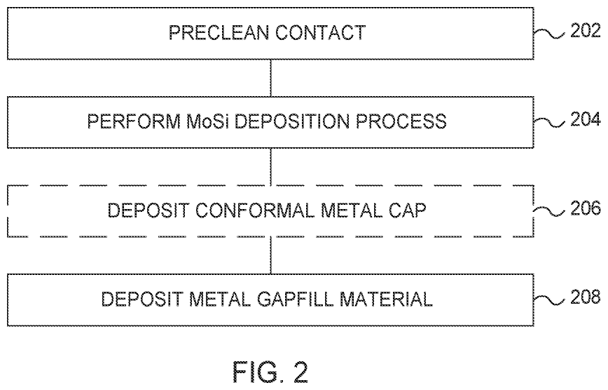

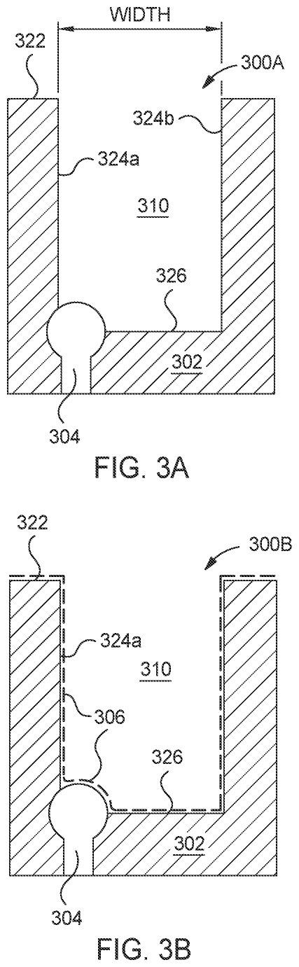

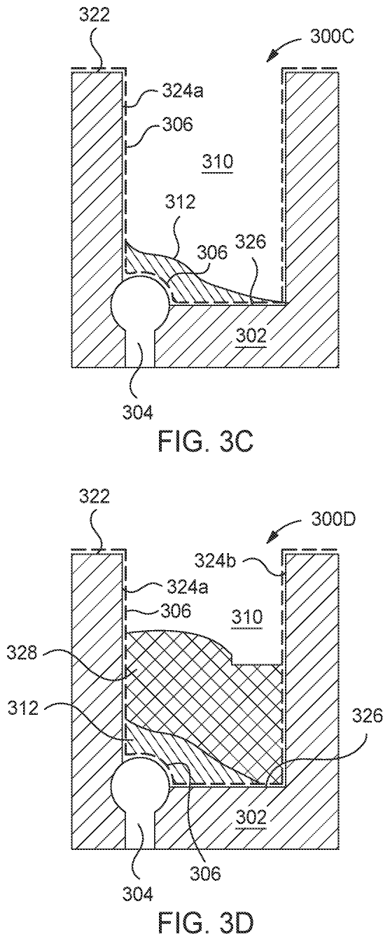

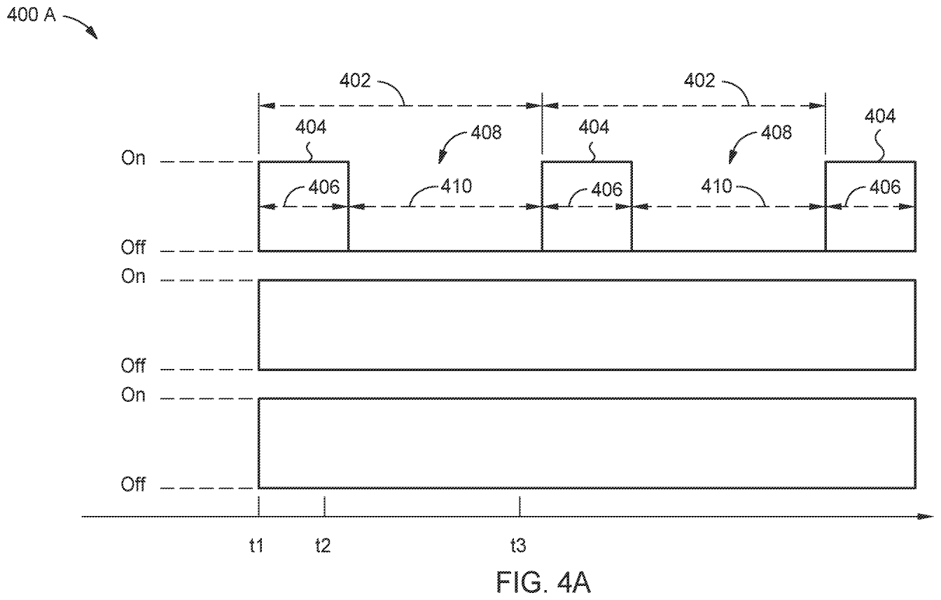

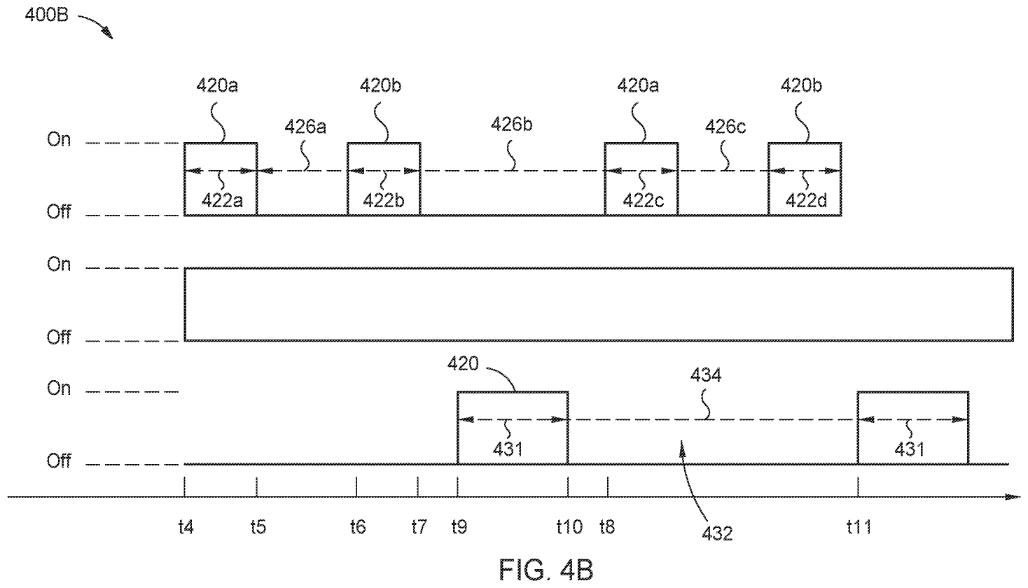

FIG. 2 illustrates a method for depositing a contact capping layer on a substrate according to one or more embodiments. FIGS. 3A-3B illustrate a cross-sectional view of a semiconductor structure during deposition of a contact capping layer according to one or more embodiments. FIGS. 4A-4B illustrate timing diagrams illustrating a process for depositing a contact capping layer on a substrate according to one or more embodiments. In the method 200 of FIG. 2, a controllable ALD deposition process is able to provide control over the thickness and the impurities of the deposited contact capping layer, improving the total device resistance by reducing the contact resistance. In the discussion of the method 200, references will be made to the views 300A-300B of FIGS. 3A-3B and FIGS. 4A-4B.

At block 202, a preclean process is performed to remove any contaminates and/or oxidation from surfaces of a contact structure as depicted in a view 300A of FIG. 3A. The contact structure has a silicon-based portion 304 (i.e., a contact) that is exposed in a cavity 310 of a semiconductor substrate 302 formed of a dielectric material (e.g., silicon dioxide, silicon nitride, etc.). In some embodiments, the silicon-based portion 304 may be a silicon material or a silicon germanium (SiGe) material.

In one or more embodiments, cavities (e.g., vias) can have an average width. For example, cavity 310 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

At block 204, as depicted in view 300B of FIG. 3B, a contact capping layer deposition process is performed to produce a contact capping layer 306. The contact capping layer 306 may be a conformal capping layer, such as a molybdenum silicide (MoSi) layer. In one or more examples, the contact capping layer 306 is deposited selective to the silicon-based portion 304 over the dielectric material of the semiconductor substrate 302, but the contact capping layer 306 may also form on the surfaces of the field 322 of the semiconductor substrate 302 and on sidewalls 324a, 324b in the cavity 310, including a bottom surface 326 of the cavity 310.

Advantageously, and as described above, the contact capping layer deposition process allows for control over the thickness of the contact capping layer 306, and reduces impurities within the contact capping layer 306. In one example, the contact capping layer deposition process may use any suitable deposition process, such as a soaking process, using a molybdenum (Mo) precursor, such as molybdenum pentachloride (MoCl₅), hydrogen (H₂), and a silicon containing gas as processes gasses. In one example the silicon containing gas may comprise silane (SiH₄), disilane (Si₂H₆), or the like.

FIG. 4A illustrates a contact capping layer deposition process 400A, according to one or more embodiments. In one example, the contact capping layer deposition process 400A may include co-flowing silane as the silicon containing gas and hydrogen (H₂) into a process chamber while alternating between dosing (i.e. adding) and purging the Mo precursor from the processing chamber. The process gases may be flowed into the process chamber in the presence of a carrier gas. The carrier gas may include a noble gas such as argon (Ar).

FIG. 4A illustrates how a sequence of the process gases are flowed into the processing chamber with respect to time (i.e. during the contact capping layer deposition process 400A). For example, throughout the deposition process, silane and hydrogen are continually flowed into the chamber. In one example, hydrogen may be flowed at a flow rate between 1 and 20 standard liters per minute (slm), the silicon containing gas (e.g., silane) may be flowed at a flow rate between 1 and 500 standard cubic centimeters per minute (sccm), and the carrier gas may be flowed at a rate between 300-1000 sccm. The pressure of the processing chamber may be between 20 and 500 Torr, the substrate pedestal and substrate temperature may be between 30° and 400° C., and an ampoule temp of the Mo precursor may be between 65 and 120° C.

On the other hand, the Mo precursor is alternately dosed (i.e., on) and purged (i.e., off) into the processing chamber in cycles. For example, a Mo precursor cycle 402 includes a Mo precursor dose pulse 404 (i.e., on-time) and a Mo precursor purge 408 (i.e., off time). The Mo precursor dose pulse 404 may be performed over a period of time defined herein as the Mo precursor dose period 406. During the Mo precursor dose period 406 of each Mo precursor dose pulse 404, the Mo precursor is flowed into the processing chamber. The Mo precursor purge 408 may be performed over a period of time defined herein as the Mo precursor purge period 410. The Mo precursor purge period 410 is a period of time in which the Mo precursor is purged from the processing chamber. The Mo precursor purge 408 occurs after the Mo precursor dose pulse 404 during a single Mo precursor cycle 402.

The duration of the Mo precursor dose period 406 and the Mo precursor purge period 410 are equal to the Mo precursor cycle 402 period. For example, the Mo precursor dose period 406 may occur between a time t1 and a time t2. The Mo precursor purge period 410 may occur between a time t2 and a time t3. Therefore, the Mo precursor cycle may occur between the time t1 and the time t3. Stated differently, the Mo precursor cycle 402 ranges between the start of two Mo precursor doses. In one example, the Mo precursor dose period 406 may range between 0.3 and 6 seconds and the Mo precursor purge period 410 may range between 1 and 10 seconds. A ratio between the Mo precursor dose period 406 and the Mo precursor purge period 410 may range between 0.3:10 and 6:10. For example the ratio between the Mo precursor dose period 406 and the Mo precursor purge period 410 may range between 1:1-1:30. In another example the ratio between the Mo precursor dose period 406 and the Mo precursor purge period 410 may range between 1:3 and 1:10. The Mo precursor may be continued to be pulsed throughout the deposition process.

In one example, the contact capping layer deposition process 400A is initiated by beginning to flow hydrogen and silane into the processing chamber. In one example, as shown in FIG. 4A, a first Mo precursor cycle 402 may begin when the contact capping layer deposition process 400A is initiated. For example, the time t1 may occur at the same time as when hydrogen and silane are introduced into the processing chamber. In other examples, a first Mo precursor cycle 402 may occur at a period of time after hydrogen and silane are introduced into the processing chamber. For example, the time t1 may occur after hydrogen and silane are introduced into the processing chamber.

In another example, a contact capping layer deposition process may include flowing hydrogen into the processing chamber while alternating between dosing (i.e. adding) and purging the Mo precursor and the silicon containing gas from the processing chamber. Stated differently, both the Mo precursor and the silicon containing gas may be intermittently flowed into the processing chamber.

FIG. 4B illustrates a contact capping layer deposition process 400B, according to one or more embodiments. In one example, the contact capping layer deposition process 400B includes a first Mo precursor dose pulse 420a, a first Mo precursor purge 424a, a second Mo precursor dose pulse 420b, a second Mo precursor purge 424b, a silicon containing gas dose 430, and a silicon containing gas purge 432. As described above, the silicon containing gas may comprise silane (SiH₄), disilane (Si₂H₆), or the like.

During the first Mo precursor dose pulse 420a and the second Mo precursor dose pulse 420b, the Mo precursor is flowed into a processing chamber (i.e., on-time). During the first Mo precursor purge 424a and the second Mo precursor purge 424b, the Mo precursor is purged from the processing chamber. The first Mo precursor dose pulse 420a is followed by the first Mo precursor purge 424a. The second Mo precursor dose pulse 420b is followed by the second Mo precursor purge 424b. The first Mo precursor dose pulse 420a may be performed over a first Mo precursor dose period 422a. The second Mo precursor dose pulse 420b may be performed over a second Mo precursor dose period 422b. The first Mo precursor purge 424a may be performed over a first Mo precursor purge period 426a. The second Mo precursor purge 424b may be performed over a second Mo precursor purge period 426b. The contact capping layer deposition process 400B includes cycling between (i.e., alternating) between performing the first Mo precursor dose pulse 420a followed by the first Mo precursor purge 424a, and the second Mo precursor dose pulse 420b followed by the second Mo precursor purge 424b. In some embodiments, a plurality of first pulse cycles, which include the first Mo precursor dose pulse 420a and the first Mo precursor purge 424a are performed before the second Mo precursor dose pulse 420b and the second Mo precursor purge 424b are performed. In some embodiments, a plurality of second pulse cycles, which include the second Mo precursor dose pulse 420b and the second Mo precursor purge 424b are performed after a first Mo precursor dose pulse 420a and a first Mo precursor purge 424a are performed. In either case, the silicon containing gas dose 430 may be performed during a Mo precursor purge period, such as during each of the first Mo precursor purges 426a performed during each of the plurality of first pulse cycles and/or during each of the second Mo precursor purge periods 426b performed during each of the plurality of second pulse cycles.

In one example, the first Mo precursor dose period 422a and the second Mo precursor dose period 422b are equal durations of time. The first Mo precursor purge period 426a and the second Mo precursor purge period 426b are different durations of time. The duration of the first Mo precursor purge period 426a may be less than the second Mo precursor purge period 426b (or vice versa). For example, the first Mo precursor dose period 422a may occur between a time t4 and a time t5, the first Mo precursor purge period 426a may occur between the time t5 and a time t6, the second Mo precursor dose period 422b may occur between the time t6 and a time t7, the second Mo precursor purge period 426b occurs between the time t7 and a time t8.

Alternatively, the durations of the first Mo precursor dose period 422a and the second Mo precursor dose period 422b may be different and/or the durations of the first Mo precursor purge period 426a and the second Mo precursor purge period 426b may be the same.

In one example, the dosing of the Mo precursor (i.e., the first Mo precursor dose pulse 420a and the second Mo precursor dose pulse 420b) and the silicon containing gas dose 430 are not performed at the same time. The silicon containing gas dose 430 may be performed during a Mo precursor purge (i.e., the first or the second Mo precursor purges 424a and 424b). The silicon containing gas dose 430 is performed over a silicon containing gas dose period 431. Each silicon containing gas dose 430 is separated by a silicon containing gas purge 432. Each silicon containing gas purge 432 may be performed over a silicon containing gas purge period 434. In one example, the silicon containing gas dose period 431 has a shorter duration than the first Mo precursor purge period 426a and/or the second Mo precursor purge period 426b.

As noted above each silicon containing gas dose 430 does not occur during the delivery of a Mo precursor dose pulse. For example, as illustrated in FIG. 4B each silicon containing gas dose 430 may occur during each second Mo precursor purge 424b. Because the silicon containing gas period 431 has a shorter duration than the second Mo precursor purge period 426b, the silicon containing gas dose 430 can begin at a period of time after the second Mo precursor purge 424b begins and can end at a period of time before the second Mo precursor purge 424b ends. For example, the silicon containing gas dose 430 may occur between a time t9 and a time t10. Stated differently the duration of time between the time t9 and the time t10 is less than the duration of time between the time t7 and the time t8. Thus, ensuring or minimizing the interaction of a Mo precursor provided during a Mo precursor dose pulse with a silicon containing gas provided during the silicon containing gas dose 430. At the conclusion of each silicon containing gas dose 430, each silicon containing gas purge 432 begins. For example, a silicon containing gas purge period 434 may occur between a time t10 and a time t11. Then at the time t11, a silicon containing gas dose 430 is performed. Stated differently each silicon containing gas purge 432 may have a silicon containing gas purge period equal to the duration of time between a time t10 and a time t11.

In another example, the silicon containing gas dose 430 may begin at the same time as the second Mo precursor purge 424b (i.e., at the time t7). In yet another example, the silicon containing gas dose 430 may occur during each first Mo precursor purge period 426a, occur during both the first Mo precursor purge period 426a and the second Mo precursor purge period 426b, or alternate between being performed during the first Mo precursor purge period 426a and the second Mo precursor purge period 426b.

In one example, hydrogen (H₂) may be flowed at a flow rate between 1 and 20 standard liters per minute (slm), the silicon containing gas (e.g., silane) may be flowed at a flow rate between 1 and 500 standard cubic centimeters per minute (sccm), and the carrier gas may be flowed at a flow rate between 300 and 1000 sccm. The pressure of the processing chamber may be between 20 and 500 Torr, the substrate pedestal and substrate temperature may be between 30° and 400° C., and an ampoule temp of Mo precursor may be between 65 and 120° C.

In one example, the first Mo precursor dose period 422a may range between 0.3 and 6 seconds. The first Mo precursor purge period 426a may be between 1 and 10 seconds. A ratio between the first Mo precursor dose period 422a and the first Mo precursor purge period 426a may range between 0.3:10 and 6:10. For example, the ratio between the first Mo precursor dose period 422a and the first Mo precursor purge period 426a may range between 1:1 and 1:30. For example, the ratio between the first Mo precursor dose period 422a and the first Mo precursor purge period 426a may range between 1:3 and 1:10

The second Mo precursor dose period 422b may range between 0.3 and 6 seconds. The second Mo precursor purge period 426b may range between 10 and 180 seconds. A ratio between the second Mo precursor dose period 422b and the second Mo precursor purge period 426b may range between 0.3:10 and 0.3:180. For example, the ratio between the second Mo precursor dose period 422b and the second Mo precursor purge period 426b may be between 1:2 and 1:300. For example, the ratio between the second Mo precursor dose period 422b and the second Mo precursor purge period 426b may be between 1:10 and 1:100

The silicon containing gas dose period 431 may range between 1 and 60 seconds, and the silicon containing gas purge period 434 may range between 5 and 120 seconds. A ratio between the silicon containing gas dose period 431 and the silicon containing gas purge period 434 may range between 1:5 and 1:120. For example the ration between the silicon containing gas dose period 431 and the silicon containing gas purge period 434 may range between 1:1 and 1:30. The Mo precursor and the silicon containing gas may be continued to be pulsed throughout the deposition process. As noted above, the silicon containing gas dose period 431 occurs during the second Mo precursor purge period 426b. A ratio between the second Mo precursor purge period 426b and the silicon containing gas dose period 431 may range between 180:1 and 10:60. For example the ratio between the second Mo precursor purge period 426b and the silicon containing gas dose period 431 may range between 100:1 and 2:1. For example the ratio between the second Mo precursor purge period 426b and the silicon containing gas dose period 431 may range between 10:1 to 3:1.

In optional block 206, a partially selective metal cap 312 is deposited on the contact capping layer 306 on the silicon-based portion 304 as depicted in a view 300C of FIG. 3C. In some embodiments, a partially selective metal cap has an average thickness of about 5 nm to about 11 nm, such as about 6 nm to about 9 nm, such as about 8 nm. The partially selective metal cap 312 can be deposited by any suitable deposition process, such as CVD or ALD. The partially selective metal cap 312 may be deposited using a partially selective deposition process that is a fluorine free metal deposition process of the metal material used for forming the partially selective metal cap 312. In some embodiments, the partially selective metal cap 312 may be formed of tungsten. In some embodiments, the partially selective metal cap 312 may be formed of molybdenum. For example, in some embodiments, an in-situ partially selective FFW material is deposited on the contact capping layer 306 as a silicide capping layer. In some embodiments, the partially selective FFW process can be from a halide based atomic layer deposition (ALD) process. In some embodiments, the partially selective FFW process can be from a metal chloride process such as from a CVD (WCl5+H₂) process or from a CVD (WCl6+H₂) process. In some embodiments, the partially selective FFW process can be from a process using metalorganic precursors.

Partially selective metal cap 312 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or combinations thereof. In some embodiments, the partially selective metal cap 312 may be formed of tungsten. In some embodiments, the partially selective metal cap 312 may be formed of molybdenum. In some embodiments, for example, a partially selective metal cap provides metal seeding on a bottom of the cavity 310 (e.g., SiO2 or SiN surface where partially selective FFW has grown).

As part of a process of depositing the partially selective metal cap 312 onto the contact capping layer 306 during block 206, both a metal-containing precursor and a reducing agent are introduced in the process chamber with a carrier gas to form a gas mixture. The gas mixture is then introduced towards the surface of the semiconductor substrate 302. The carrier gas may include a noble gas, such as argon, neon, and helium, and combinations thereof.

As part of a process of depositing the partially selective metal cap 312 onto the contact capping layer 306, the semiconductor substrate 302 may be maintained at a metal deposition temperature. In one or more embodiments, the semiconductor substrate 302 is maintained at a metal deposition temperature of about 300° C. to 450° C., such as from about 300° C., 325° C., 350° C., 375° C., to about 375° C., about 400° C., about 425° C. or 450° C., such as about 350° C. to about 370° C. In one or more embodiments, a chamber pressure at which the partially selective metal deposition process is performed is about 50 T to about 150 T, such as about 80 T to about 120 T, such as about 80 T to about 100 T, alternatively about 100 T to about 120 T. In one or more embodiments, the period of time at which the partially selective metal deposition process is performed is about 5 seconds to about 45 seconds, such as about 30 seconds or less, such as about 10 seconds to about 25 seconds. In one or more embodiments, both the MoSi deposition process and the partially selective metal deposition process occur in the same process chamber or in different process chambers.

The partially selective metal cap 312 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a partially selective metal cap 312 onto the contact capping layer 306 during block 206, a reducing agent that is reactive with a metal-containing precursor is introduced into the carrier gas along with the metal-containing precursor. The reducing agent may be a hydrogen-containing composition, such as molecular hydrogen (H₂), ammonia (NH₃), hydrazine (N₂H₄), silane (SiH₄), disilane (Si₂H₆), trisilane (Si₃H₈), and tetrasilane (Si₄H₁₀), or combinations thereof. The reducing agent acts as a proton donor to cause the metal-containing precursor to form a metallic film comprising the metal on top of the contact capping layer 306.

The deposition process may include maintaining a flow rate of the metal-containing precursor to a flow rate of the reducing agent into the carrier gas until a partially selective metal cap 312 forms on the contact capping layer 306. In one or more embodiments, reducing agent (e.g., H₂) is provided to the chamber at a flow rate of about 10 slm or greater, such as about 10 sim to about 100 slm, such as about 15 slm to about 50 slm. In one or more embodiments, the metal-containing precursor is provided to the chamber at an ampoule temperature of about 100° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

In block 208, a metal gap fill material 328 is deposited in a bottom-up selective process (e.g., a tungsten hexafluoride (WF₆) based selective process (tungsten over dielectric material of the sidewalls 324a, 324b of the cavity 310, etc.)) as depicted in a view 300D of FIG. 3D.

In some embodiments, a conformal gap fill may be used instead of a bottom-up fill. In some embodiments, for example, the cavity 310 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors. Similarly, the structure fill can be done by selective Mo fill or conformal Mo fill. In some embodiments, Mo and W materials can be interchanged or mixture of Mo and W used.

In FIG. 3D, a resultant conformal metal gap fill material 328 has been conformally deposited into cavity 310. In FIG. 3D, metal gap fill material 328 is shown filling the device cavity 310. The metal gap fill material 328 is shown in contact with the partially selective metal cap 312 such that the metal gap fill material 328 is in electrical communication with the silicon-based portion 304 or the metal gap fill material is in contact with the contact capping layer 306 (not shown). The metal gap fill material 328 is also in contact with at least a portion of the sidewalls 324a, 324b.

Any suitable chemical deposition process, including but not limited to CVD or ALD processes, may be utilized for the metal gap fill material process. The metal gap fill material may be applied such that the material is deposited onto the bottom portion of the device feature and then grown upwards.

In one or more embodiments, the metal gap fill material 328 includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gap fill material 328 includes tungsten (e.g., deposited using WF₆). In one or more embodiments, the conductor material includes molybdenum.

What is claimed is:

1. A method comprising:
depositing a contact capping layer over a surface of a contact structure, the contact capping layer deposition process comprising:
flowing hydrogen (H₂) and a silicon containing gas into a processing chamber for a first period of time;
delivering a molybdenum (Mo) precursor for a second period of time and halting delivering of the Mo precursor for a third period of time, wherein the second period of time and the third period of time overlap with the first period of time; and
repeating delivering the Mo precursor and halting delivering the Mo precursor one or more times.

2. The method of claim 1, further comprising selectively depositing a metal cap on the contact capping layer using a fluorine free metal (FFW) deposition process, the metal cap comprising cobalt (Co), molybdenum (Mo), tungsten (W), or combinations thereof.

3. The method of claim 2, wherein the metal cap has an average thickness between 5 and 11 nm.

4. The method of claim 3, further comprising depositing a metal gap fill material on the metal cap.

5. The method of claim 1, further comprising depositing a metal gap fill material over the contact capping layer.

6. The method of claim 5, wherein a ratio between the second period of time and the third period of time is between 0.3:10 and 6:10.

7. The method of claim 1, wherein the silicon containing gas comprises silane or disilane.

8. The method of claim 1, wherein the contact capping layer comprises molybdenum silicide (MoSi) and the surface of the contact structure comprises silicon (Si) or silicon germanium (SiGe).

9. The method of claim 1, wherein the Mo precursor comprises molybdenum pentachloride (MoCl₅).

10. A method comprising:
forming a contact capping layer over a surface of a contact structure, the forming of the contact comprising:
(a) delivering a molybdenum (Mo) precursor for a first period of time and halting the first delivery of the Mo precursor for a second period of time;
(b) delivering the molybdenum (Mo) precursor for a third period of time and halting the second delivery of the Mo precursor for a fourth period of time;
(c) delivering a silicon containing gas for a fifth period of time and halting delivery of the silicon containing gas for a sixth period of time; and
(d) repeating (a), (b) and (c) one or more times while flowing hydrogen (H₂).

11. The method of claim 10, wherein the silicon containing gas comprises silane or disilane.

12. The method of claim 10, wherein the fifth period of time occurs during the fourth period of time.

13. The method of claim 10, wherein a ratio between the first period of time and the second period of time is between 0.3:10 and 6:10.

14. The method of claim 10, wherein a ratio between the third period of time and the fourth period of time is between 1:2 and 1:300.

15. The method of claim 10, wherein a ratio between the fifth period of time and the sixth period of time is between 1:1 and 1:30.

16. The method of claim 10, wherein a ratio between the fourth period of time and the fifth period of time is between 180:1 and 10:60.

17. The method of claim 10, further comprising selectively depositing a metal cap on the contact capping layer using a fluorine free metal (FFW) deposition process, the metal cap comprising cobalt (Co), molybdenum (Mo), tungsten (W), or combinations thereof.

18. The method of claim 10, further comprising depositing a metal gap fill material over the contact capping layer.

19. The method of claim 10, wherein the contact capping layer comprises molybdenum silicide (MoSi) and the surface of the contact structure comprises silicon (Si) or silicon germanium (SiGe).

20. The method of claim 1, wherein the Mo precursor comprises molybdenum pentachloride (MoCl₅).
